(19) United States
(12) Patent Application Publication
(10) Pub. No.: US 2026/0013227 A1
(43) Pub. Date: Jan. 8, 2026

(54) Array Substrate, Array Motherboard, Display Panel and Display Device

(71) Applicants: BEIJING BOE OPTOELECTRONICS TECHNOLOGY CO., LTD., Beijing (CN); BOE TECHNOLOGY GROUP CO., LTD., Chaoyang District, Beijing (CN)

(72) Inventors: Xian Wang, Beijing (CN); Yashuai An, Beijing (CN); Yong Zhang, Beijing (CN); Hongjun Yu, Beijing (CN); Yang Ge, Beijing (CN); Lei Shi, Beijing (CN); Xingxing Guan, Beijing (CN); Jianwei Ma, Beijing (CN); Xinxin Zhao, Beijing (CN)

(21) Appl. No.: 18/726,564

(22) PCT Filed: Apr. 26, 2023
(86) PCT No.: PCT/CN2023/090985

§ 371 Date: Jul. 3, 2024

(51) Int. Cl. H10D 86/40; G02F 1/1362; G09G 3/00; G09G 3/36; H10D 86/60

(52) U.S. Cl. CPC H10D 86/441; G02F 1/136222; G02F 1/136254; G02F 1/136286; G09G 3/006; G09G 3/3677; H10D 86/60; G09G 2330/12

(57) ABSTRACT

An array substrate has a display area and a first frame area which includes a chip setting area and bonding areas. In a second direction, the bonding areas are located on at least one side of the chip setting area. The array substrate includes driving pads in the chip setting area, bonding pins in a bonding area, and peripheral connection lines in the first frame area. An end of each peripheral connection line is connected to a driving pad, and another end thereof is connected to a bonding pin. The peripheral connection lines include first peripheral connection lines extending to a side of the chip setting area proximate to the bonding area in the chip setting area. An end of a first peripheral connection line is connected to a driving pad in the chip setting area, and another end thereof is connected to a bonding pin in the bonding area.

### CROSS-REFERENCE TO RELATED APPLICATION

This application is the United States national phase of International Patent Application No. PCT/CN2023/090985, filed Apr. 26, 2023, the disclosure of which is hereby incorporated by reference in its entirety.

### BACKGROUND OF THE INVENTION

### Field of the Invention

The present disclosure relates to the field of display technologies, and in particular, to an array substrate, an array motherboard, a display panel and a display device.

### Description of Related Art

With the rapid development of display technologies, a liquid crystal display (LCD) device, an organic light-emitting display (OLED) device, a quantum dot light-emitting display (QLED) device, a mini/micro light-emitting display (MLED) device, and other display technologies have been widely penetrated into people's daily lives. For example, smart phones, wearable watches, televisions, notebook computers, and car monitors have been gradually spread in people's lives. Currently, how to reduce a frame of the display device and increase a screen-to-body ratio of the display device has always been a direction of research and tackle of display technology.

### SUMMARY OF THE INVENTION

In an aspect, an array substrate is provided. The array substrate has a display area and a first frame area arranged in a first direction. The first frame area includes a chip setting area and bonding areas. In a second direction, the bonding areas are located on at least one side of the chip setting area. The second direction intersects the first direction.

The array substrate includes a plurality of driving pads, a plurality of bonding pins and a plurality of peripheral connection lines. The plurality of driving pads are disposed in the chip setting area. The plurality of bonding pins are disposed in a bonding area. The plurality of peripheral connection lines are disposed in the first frame area, an end of each peripheral connection line is connected to a driving pad, and another end of each peripheral connection line is connected to a bonding pin. The plurality of peripheral connection lines include first peripheral connection lines, and the first peripheral connection lines extend to a side of the chip setting area proximate to the bonding area in the chip setting area. An end of a first peripheral connection line is connected to a driving pad in the chip setting area, and another end of the first peripheral connection line is connected to a bonding pin in the bonding area.

In some embodiments, the plurality of driving pads are arranged into a plurality of driving pad groups, and the plurality of driving pad groups include an output pad group and an input pad group. The output pad group includes a plurality of output pads arranged in the second direction. The input pad group includes a plurality of input pads arranged in the second direction. The input pad group is located on a side of the output pad group away from the display area. The first peripheral connection lines extend to the side of the chip setting area proximate to the bonding area between the input pad group and the output pad group. The driving pad connected to the end of the first peripheral connection line is an input pad, the end of the first peripheral connection line is connected to an end of the input pad proximate to the output pad group, and the another end of the first peripheral connection line is connected to an end of the bonding pin proximate to the display area.

In some embodiments, the plurality of peripheral connection lines further include second peripheral connection lines. The second peripheral connection lines extend to the side of the chip setting area proximate to the bonding area at a side of the chip setting area away from the display area. A driving pad connected to an end of a second peripheral connection line is another input pad, the end of the second peripheral connection line is connected to an end of the another input pad away from the output pad group, and another end of the second peripheral connection line is connected to an end of another bonding pin in the bonding area proximate to the display area.

In some embodiments, the bonding pin connected to the first peripheral connection line is a first bonding pin, and the another bonding pin connected to the second peripheral connection line is a second bonding pin. The first bonding pin is farther away from the chip setting area than the second bonding pin, and the second peripheral connection line is located at a side of the first peripheral connection line away from of the display area.

In some embodiments, the input pad group includes a plurality of input pad sub-groups, and the input pad sub-groups each include multiple input pads disposed adjacently and for transmitting a same signal. The second peripheral connection lines include at least one first type of second peripheral connection line and a second type of second peripheral connection line. The at least one first type of second peripheral connection line are connected to a bonding pin and an input pad sub-group. The second type of second peripheral connection line is connected to a bonding pin and at least two input pad sub-groups. The second type of second peripheral connection line is located on a side of the at least one first type of second peripheral connection line away from the display area.

In some embodiments, the bonding areas are located on opposite sides of the chip setting area in the second direction. The at least one first type of second peripheral connection line includes two first type of second peripheral connection lines. The two first type of second peripheral connection lines are each connected to an input pad sub-group and a bonding pin on a first side of the chip setting area. The two first type of second peripheral connection lines are disposed away from the display area in sequence. The second type of second peripheral connection line includes one second type of second peripheral connection line. The one second type of second peripheral connection line is connected to the bonding pin on the first side of the chip setting area and two input pad sub-groups. The one second type of second peripheral connection line is located on the side of the two first type of second peripheral connection lines away from the display area.

In some embodiments, the input pad group includes a plurality of input pad sub-groups, and the input pad sub-groups each include multiple input pads disposed adjacently and for transmitting a same signal. The array substrate further includes an input transfer line, and the input transfer line is disposed in the chip setting area and connected to at least two input pad sub-groups. An input pad sub-group in the at least two input pad sub-groups is further connected to a second peripheral connection line.

In some embodiments, the bonding areas are located on opposite sides of the chip setting area in the second direction. The second peripheral connection lines include two first type of second peripheral connection lines. The two first type of second peripheral connection lines are each connected to an input pad sub-group and a bonding pin on a second side of the chip setting area. The two first type of second peripheral connection lines are disposed away from the display area in sequence.

The input transfer line is connected to three input pad sub-groups. In the three input pad sub-groups, two input pad sub-groups and one input pad sub-group are respectively located on opposite sides of an input pad sub-group connected to a first type of second peripheral connection line further away from the display area in the two first type of second peripheral connection lines, and the one input pad sub-group is connected to another first type of second peripheral connection line closer to the display area in the two first type of second peripheral connection lines.

In some embodiments, the array substrate further includes a plurality of sub-pixels, a plurality of data lines, a plurality of scan lines and a test circuit. The plurality of sub-pixels are disposed in the display area. The plurality of data lines are connected to the plurality of sub-pixels. The plurality of scan lines are connected to the plurality of sub-pixels. The test circuit is connected to the plurality of data lines, the plurality of scan lines and the plurality of sub-pixels.

In some embodiments, the sub-pixels include a common electrode. The test circuit includes a first test circuit, a second test and a first test signal line. The first test circuit is connected to the plurality of data lines. The second test circuit is connected to the plurality of scan lines. The first test signal line is connected to the common electrode of the plurality of sub-pixels.

In some embodiments, the test circuit further includes first test pads. The first test pads are disposed between the plurality of peripheral connection lines and the display area. The first test circuit, the second test circuit, and the first test signal line are connected to the first test pads.

In some embodiments, the test circuit further includes a plurality of residual transfer lines. The plurality of residual transfer lines are disposed between the bonding area and the chip setting area. The residual transfer lines extend to an edge of the array substrate located in the first frame area in the first direction. The first test circuit, the second test circuit, and the first test signal line are connected to the residual transfer lines.

In some embodiments, the plurality of driving pads are arranged into a plurality of driving pad groups, and the plurality of driving pad groups include an output pad group and an input pad group. The output pad group includes data output pads, and the data output pads are each connected to a data line. The first test circuit is disposed between the input pad group and the output pad group and is connected to the data output pads.

In some embodiments, the array substrate further has a second frame area, a third frame area and a fourth frame area. The second frame area is located on a side of the display area away from the first frame area. The third frame area and the fourth frame area are located on opposite sides of the display area in the second direction. The first test circuit is disposed in the second frame area and is connected to the plurality of data lines.

In some embodiments, the plurality of data lines include a first data line, a second data line and a third data line. The plurality of sub-pixels include a sub-pixel connected to the first data line, a sub-pixel connected to the second data line, and a sub-pixel connected to the third data line.

The first test circuit includes a first data test line, a second data test line, a third data test line, a first transistor, a second transistor, a third transistor and a first switch signal line.

A first electrode of the first transistor is connected to the first data test line, and a second electrode of the first transistor is connected to the first data line. A first electrode of the second transistor is connected to the second data test line, and a second electrode of the second transistor is connected to the second data line. A first electrode of the third transistor is connected to the third data test line, and a second electrode of the third transistor is connected to the third data line. The first switch signal line is connected to gates of the first transistor, the second transistor and the third transistor.

In some embodiments, the plurality of sub-pixels are arranged in a plurality of rows and a plurality of columns. The scan lines include a first scan line and a second scan line. The first scan line is connected to sub-pixels in an odd row, and the second scan line is connected to sub-pixels in an even row. The plurality of driving pads include a plurality of first scan output pads and a plurality of second scan output pads.

The array substrate further includes a first scan connection line and a first scan output pad. The first scan connection line is connected to the first scan line and a first scan output pad, and the second scan connection line is connected to the second scan line and a second scan output pad.

The second test circuit includes a first scan test line, a second scan test line, a fourth transistor, a fifth transistor and a second switch signal line. A first electrode of the fourth transistor is connected to the first scan test line, and a second electrode of the fourth transistor is g connected to the first scan output pad. A first electrode of the fifth transistor is connected to the second scan test line, and a second electrode of the fifth transistor is connected to the second scan output pad. The second switch signal line is connected to gates of the fourth transistor and the fifth transistor.

In some embodiments, the first test circuit includes a first switch signal line, and the second switch signal line and the first switch signal line are a same signal line.

In some embodiments, the plurality of driving pads include scan output pads. The array substrate further includes a gate driver circuit and a gate control signal line. The gate driver circuit is connected to the plurality of scan lines. The gate control signal line is connected to the gate driver circuit and a scan output pad. The second test circuit includes a plurality of gate control test lines, and the plurality of gate control test lines are connected to the scan output pads.

In some embodiments, the plurality of driving pads include a common voltage pad. The common voltage pad is connected to the common electrode of the plurality of sub-pixels, and the first test signal line is connected to the common voltage pad.

In some embodiments, the plurality of driving pads are arranged into a plurality of driving pad groups, and the plurality of driving pad groups include an output pad group and input pad groups. The output pad group includes a plurality of output pads arranged in the second direction. The input pad groups each include a plurality of input pads arranged in the second direction. The input pad groups are located on at least one side of the output pad group in the second direction.

An edge of the plurality of driving pad groups proximate to the display area substantially coincides with an edge of the chip setting area proximate to the display area. The first peripheral connection lines extend to the side of the chip setting area proximate to the bonding area at a side of the plurality of driving pad groups away from the display area. The driving pad connected to the end of the first peripheral connection line is an input pad group, the end of the first peripheral connection line is connected to an end of the input pad group away from the display area, and the another end of the first peripheral connection line is connected to an end of the bonding pin proximate to the display area.

Alternatively, an edge of the plurality of driving pad groups away from the display area substantially coincides with an edge of the chip setting area away from the display area. The first peripheral connection lines extend to the side of the chip setting area proximate to the bonding area at a side of the plurality of driving pad groups proximate to the display area. The driving pad connected to the end of the first peripheral connection line is an input pad group the end of the first peripheral connection line is connected to an end of the input pad group proximate to the display area, and the another end of the first peripheral connection line is connected to an end of the bonding pin proximate to the display area.

In some embodiments, the chip setting area and the bonding areas are each substantially in a rectangular shape. Edges of the bonding areas away from the display area are substantially flush with an edge of the chip setting area away from the display area.

In some embodiments, the plurality of peripheral connection lines further include second peripheral connection lines. A distance between the chip setting area and a first edge is a first distance, and a distance between the bonding area and the first edge is a second distance. The first edge is an edge of the first frame area of the array substrate away from the display area. The first distance is greater than the second distance.

In some embodiments, a difference between the first distance and the second distance is in a range of 0.3 mm to 0.6 mm, inclusive.

In some embodiments, the array substrate has an axis extending in the first direction. The plurality of driving pads, the plurality of bonding pins and the plurality of peripheral connection lines are each arranged symmetrically about the axis.

In another aspect, an array motherboard is provided. The array motherboard has a plurality of product areas and a plurality of areas to be cut, and every two adjacent product areas have an area to be cut therebetween. The array motherboard includes the array substrate as described in any of the above embodiments, and the array substrate is located in a product area.

In some embodiments, the array substrate includes a first test circuit, a second test circuit, a first test signal line and a plurality of residual transfer lines. The array motherboard further includes: second test pads, the second test pads being disposed in the area to be cut; and a plurality of test leads disposed in the area to be cut. A test lead is connected to a residual transfer line and a second test pad.

In some embodiments, the test lead includes a cut-off transfer line and a test connection line. The cut-off transfer line is connected to the residual transfer line. The cut-off transfer line extends in the first direction, and the cut-off transfer line and the residual transfer line are made of a same material and disposed in a same layer. The test connection line is connected to the cut-off transfer line and the second test pad.

In yet another aspect, a display panel is provided. The display panel includes the array substrate as described in any of the above embodiments and a color filter substrate. The color filter substrate is disposed opposite to the array substrate. An edge of the first frame area of the array substrate away from the display area exceeds an edge of the color filter substrate corresponding to the first frame area in the first direction, and another edge of the array substrate away from the first frame area and two edges of the array substrate in the second direction are approximately flush with respective edges of the color filter substrate. The chip setting area, the bonding areas and the peripheral connection lines of the array substrate are all located between the edge of the first frame area of the array substrate away from the display area and the edge of the color filter substrate corresponding to the first frame area.

In some embodiments, the array substrate includes first test pads, and the first test pads are disposed between the color filter substrate and the peripheral connection lines.

In yet another aspect, a display device is provided. The display device includes the display panel as described in any of the above embodiments, a driver chip and a flexible circuit board. The driver chip is connected to the driving pads in the array substrate of the display panel. The flexible circuit board is connected to the bonding pins in the array substrate of the display panel.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display device, in accordance with some embodiments;

FIG. 2A is a structural diagram of another display device, in accordance with some embodiments;

FIG. 2B is a structural diagram of yet another display device, in accordance with some embodiments;

FIG. 3 is a sectional view taken along a section line A-A′ in FIG. 2A;

FIG. 4 is an internal structural diagram of a display device, in accordance with some embodiments;

FIG. 5 is an internal structural diagram of another display device, in accordance with some embodiments;

FIG. 6A is a top view of an array substrate, in accordance with some embodiments;

FIG. 6B is a top view of another array substrate, in accordance with some embodiments;

FIG. 7 is a top view of yet another array substrate, in accordance with some embodiments;

FIG. 8 is a positional relationship diagram of driving pads and bonding pins of a display panel, in accordance with some embodiments;

FIG. 9 is a positional relationship diagram of driving pads and bonding pins of another display panel, in accordance with some embodiments;

FIG. 10 is a positional relationship diagram of driving pads and bonding pins of yet another display panel, in accordance with some embodiments;

FIG. 11 is a positional relationship diagram of driving pads and bonding pins of yet another display panel, in accordance with some embodiments;

FIG. 12A is a structural diagram of a first bonding area of a display panel, in accordance with some embodiments;

FIG. 12B is a structural diagram of a first bonding area of another display panel, in accordance with some embodiments;

FIG. 13 is a structural diagram of a first bonding area of yet another display panel, in accordance with some embodiments;

FIG. 14 is a structural diagram of a first bonding area of yet another display panel, in accordance with some embodiments;

FIG. 15A is a partial enlarged view of an area E in FIG. 12A;

FIG. 15B is a partial enlarged view of a left area in FIG. 12B;

FIG. 15C is a partial enlarged view of a right area in FIG. 12B;

FIG. 16 is a sectional view taken along a section line B-B′ in FIG. 4 or FIG. 5;

FIG. 17 is another sectional view taken along a section line B-B′ in FIG. 4 or FIG. 5;

FIG. 18 is a structural diagram of a first bonding area of yet another display panel, in accordance with some embodiments;

FIG. 19 is a partial enlarged view of an area H in FIG. 18;

FIG. 20 is a partial enlarged view of an area L in FIG. 18;

FIG. 21 is a structural diagram of a first test circuit, in accordance with some embodiments;

FIG. 22 is a structural diagram of a second test circuit, in accordance with some embodiments;

FIG. 23 is a top view of an array motherboard, in accordance with some embodiments;

FIG. 24 is a partial enlarged view of an array motherboard, in accordance with some embodiments; and

FIG. 25 is a partial enlarged view of an area J in FIG. 24.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Terms such as “first” and “second” are used herein to describe various elements, but these elements should not be limited by these terms. These terms are only used to distinguish a component from other components. For example, an element referred to as a first element in an embodiment may be called a second element in another embodiment without departing from the scope of the appended claims. Unless mentioned to the contrary, term(s) in a singular form may include a plural form.

In the description of some embodiments, the expressions “connected” and derivatives thereof may be used. The term “connection” should be understood in a broad sense. For example, the “connection” may be a fixed connection, a detachable connection, or of an integrated structure; it may be a direct connection or an indirect connection by an intermediate medium.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially”, and “approximately” as used herein includes a stated value and means to be within an acceptable range of deviation of a particular value determined by a person of ordinary skill in the art, considering measurement in question and errors associated with measurement of a particular quantity (i.e., limitations of a measurement system). For example, the term “about” may mean to be within one or more standard deviations, or within ±30%, ±20%, ±10%, or ±5% of the stated value.

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in consideration of the measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

The term such as “substantially flush with” or “substantially coincide with” as used herein includes a stated condition and a condition similar to the stated condition. A range of the similar condition is within an acceptable range of deviation. The acceptable range of deviation is determined by a person of ordinary skill in the art in consideration of the measurement in question and errors associated with the measurement of a particular quantity (i.e., limitations of the measurement system). For example, the term “substantially flush with” includes absolute flushing and approximate flushing, and an acceptable range of deviation of the approximate flushing may be a deviation within 0.05 mm. For example, the term “substantially coincide with” includes absolute coinciding and approximate coinciding, and an acceptable range of deviation of the approximate coinciding may be a deviation within 0.05 mm.

It will be understood that when a layer or element is referred to as being on another layer or substrate, the layer or element may be directly on the another layer or substrate, or there may be intermediate layer(s) between the layer or element and the another layer or substrate.

In addition, the transistors used in the embodiments of the present disclosure may be thin film transistors (TFTs), metal oxide semiconductor transistors (MOS) or other switching devices with same characteristics, and the embodiments of the present disclosure are described by taking an example in which the transistors are all thin film transistors.

Exemplary embodiments are described herein with reference to sectional views and/or plan views as idealized exemplary drawings. In the accompanying drawings, thicknesses of layers and sizes of areas are enlarged for clarity. Variations in shapes relative to the accompanying drawings due to, for example, manufacturing technologies and/or tolerances may be envisaged. Therefore, the exemplary embodiments should not be construed to be limited to the shapes of areas shown herein, but to include deviations in the shapes due to, for example, manufacturing. For example, an etched area shown in a rectangular shape generally has a feature of being curved. Therefore, the areas shown in the accompanying drawings are schematic in nature, and their shapes are not intended to show actual shapes of the areas in a device, and are not intended to limit the scope of the exemplary embodiments.

In the specification, unless otherwise defined, all terms (including technical terms and scientific terms) as used herein have the same meaning as that commonly understood by a person of ordinary skill in the art to which the present disclosure belongs. It will be further understood that, unless clearly defined here, terms (such as terms defined in a general dictionary) should be interpreted to have the same meaning consistent with that in the context of the related field, and should not be interpreted as idealistic or overly formal meaning.

In the present disclosure, terms such as “lower”, “below”, “on”, “upper”, and similar expressions are used to explain the relative association of components shown in the drawings. The above terms may be relative concepts and may be described based on direction(s) shown in the drawings, or may be described based on a sequence of process steps, but are not limited thereto.

The term “opposite” means that the first element may be directly or indirectly opposite to the second element. In a case where a third element is located between the first element and the second element, the first element and the second element may be understood to be indirectly opposite to each other although still being opposite to each other.

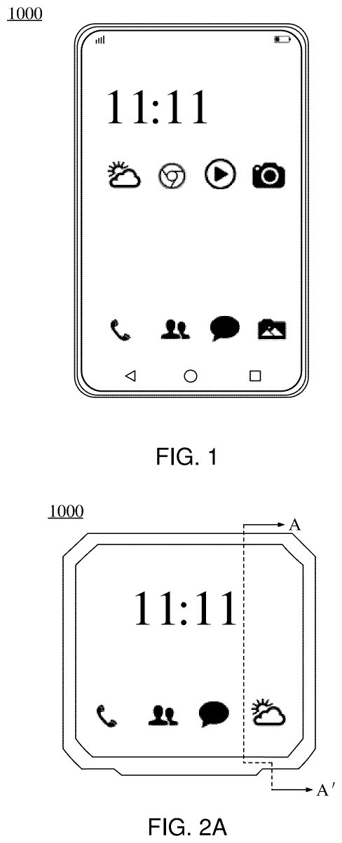

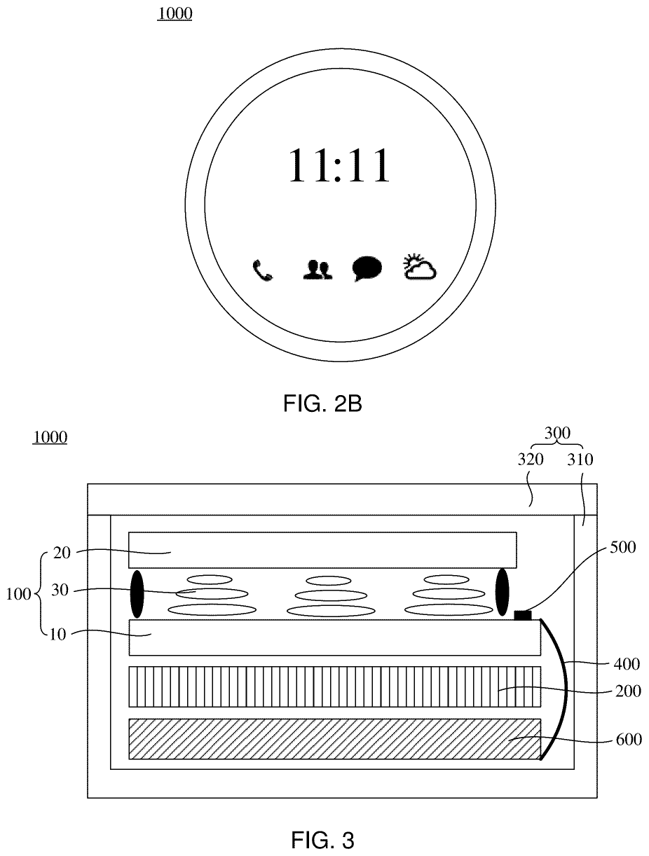

As shown in FIGS. 1 and 2A, some embodiments of the present disclosure provide a display device 1000, and the display device 1000 may be any device that displays an image whether in motion (e.g., video) or stationary (e.g., a still image), and regardless of text or image.

For example, referring to FIGS. 1 and 2A, the display device 1000 may be any product or component having a display function, such as a television, a notebook computer, a tablet computer, a mobile phone, a personal digital assistant (PDA), a navigator, a car monitor, a flight display, a wearable device or a virtual reality (VR) device.

For example, as shown in FIG. 1, the display device 1000 may be a portable display product. For example, the display device 1000 may be a smart phone shown in FIG. 1.

As another example, as shown in FIGS. 2A and 2B, the display device 1000 may be a wearable device. For example, the display device 1000 may be a smart watch shown in FIG. 2A or FIG. 2B.

In addition, the display device may be a liquid crystal display (LCD) device, an electroluminescent display device, or a photoluminescent display device. In a case where the display device is the electroluminescent display device, the electroluminescent display device may be an organic light-emitting diode (OLED) display device or a quantum dot light-emitting diode (QLED) display device. In a case where the display device is the photoluminescent display device, the photoluminescent display device may be a quantum dot photoluminescent display device.

By taking an example where the above display device 1000 is a smart watch shown in FIG. 2A and the display device 1000 is a liquid crystal display device, some embodiments of the present disclosure are schematically described below, but the embodiments of the present disclosure are not limited thereto.

On this basis, as shown in FIG. 3, the display device 1000 may include a display panel 100, a backlight module 200, a housing 300, a flexible circuit board 400, a driver chip 500, a mainboard 600 and other electronic components.

As shown in FIG. 3, the driver chip 500 is connected to the display panel 100, and the flexible circuit board 400 is connected to the display panel 100 and the mainboard 600, so that various required signals may be provided to the display panel 100.

As shown in FIG. 3, the housing 300 may include, for example, a frame 310 and a cover plate 320. The longitudinal section of the frame 310 is in a U shape. The display panel 100, the backlight module 200, the flexible circuit board 400, the driver chip 500 and the mainboard 600 are all provided in the frame 310, and the cover plate 320 is disposed at an opening of the frame 310.

As shown in FIG. 3, the backlight module 200 is disposed on a side of the display panel 100 away from the cover plate 320 and is configured to provide the display panel 100 with light required for displaying images. The backlight module 200 includes a backlight source, and the backlight source includes a plurality of light-emitting devices. The light-emitting devices may be, for example, light-emitting diodes (LEDs).

It will be noted that the plurality of light-emitting devices may have the same luminescent color or have different luminescent colors. For example, the backlight source includes a red light-emitting device with red luminescent color, a light-emitting device with green luminescent color, and a light-emitting device with blue luminescent color.

As shown in FIGS. 3, 4 and 5, the display panel 100 includes an array substrate 10, a color filter substrate 20, and a liquid crystal layer 30. The array substrate 10 and the color filter substrate 20 are arranged oppositely and aligned with each other, and the liquid crystal layer 30 is provided between the array substrate 10 and the color filter substrate 20.

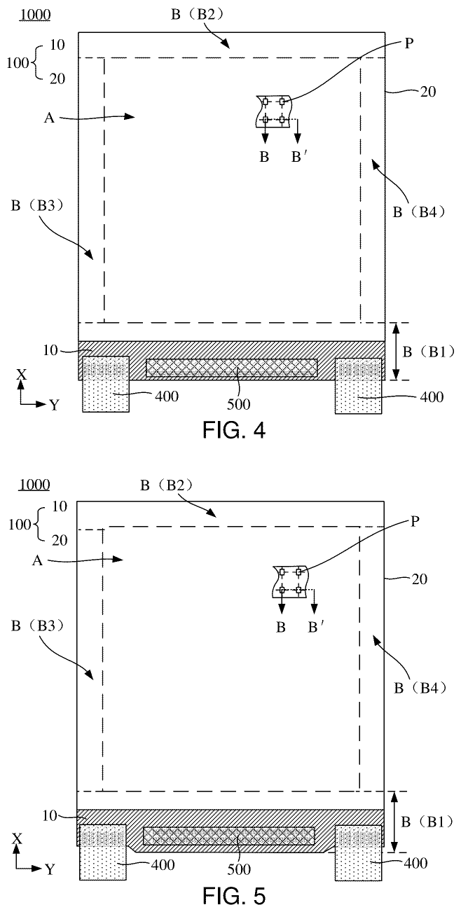

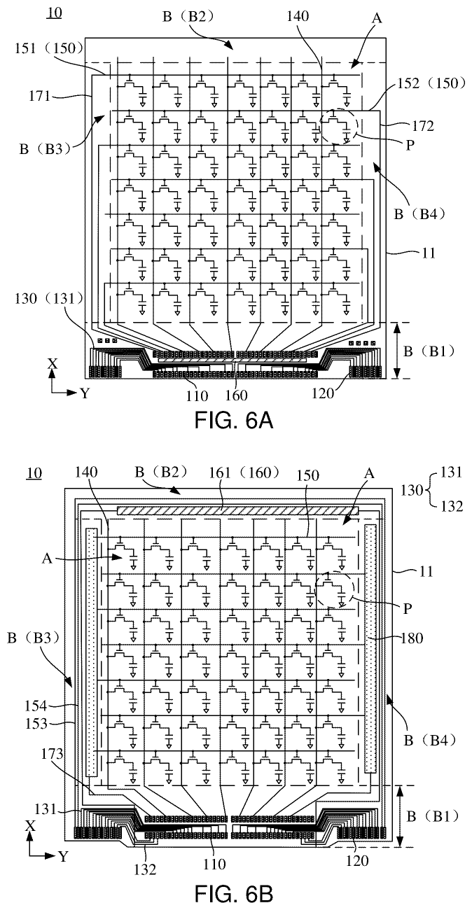

In some embodiments, as shown in FIGS. 4, 6A and 6B, the array substrate 10 has a display area A and a peripheral area B located on at least one side of the display area A.

The display area A is an area for displaying images, and is configured to be provided with a plurality of sub-pixels P and a plurality of signal lines therein. The peripheral area B is an area where no image is displayed, and is configured to be provided with drive circuits and connection lines therein.

For example, as shown in FIGS. 4 and 8, the peripheral area B includes a first frame area B1, the display area A and the first frame area B1 are arranged in a first direction X, and the first frame area B1 includes a chip setting area C and bonding areas D. The chip setting area C is configured to be provided with the driver chip 500 (referring to FIG. 3), and the bonding areas D are each configured to be connected to the flexible circuit board 400 (referring to FIG. 3).

It will be noted that the first direction X may be, for example, a direction of a line for connecting a center of the display area A and a center of the first frame area B1. The chip setting area C and the bonding areas D are each substantially in a polygonal shape. For example, the chip setting area C and the bonding areas D are each substantially in a rectangular, pentagonal, hexagonal, or irregular polygonal shape.

In the context, the expression of “substantially in a polygonal shape” means that the chip setting area C and the bonding areas D are each in a polygonal shape as a whole, but not limited to a standard polygon. That is, the “polygon” here includes not only a standard polygon but also a shape similar to the polygon in consideration of process conditions. For example, two sides of the polygon are curved at each intersecting position (i.e., a corner), that is, smooth at the corner, so that the chip setting area C and the bonding areas D are each in a shape of a round corner polygon.

By taking an example where the chip setting area C and the bonding areas D are each substantially in a rectangular shape, some embodiments of the present disclosure are schematically described below, but the embodiments of the present disclosure are not limited thereto.

It will be understood that the chip setting area C needs to be provided with the driver chip 500, and the bonding area D only needs to be connected to the flexible circuit board 400. Therefore, in the first direction X, a width of the chip setting area C may be larger than a width of the bonding area D.

For example, referring to FIG. 8, in the first direction X, the width of the bonding area D is in a range of 0.35 mm to 1 mm, inclusive. For example, in the first direction X, the width of the bonding area D is any of 0.35 mm, 0.4 mm, 0.45 mm, 0.5 mm, 0.55 mm, 0.6 mm, 0.65 mm, 0.7 mm, 0.75 mm, 0.8 mm, 0.85 mm, 0.9 mm, 0.95 mm and 1 mm.

For example, referring to FIG. 8, in the first direction X, the width of the chip setting area C is in a range of 0.6 mm to 1.2 mm, inclusive. For example, in the first direction X, the width of the chip setting area C is any of 0.6 mm, 0.65 mm, 0.7 mm, 0.75 mm, 0.8 mm, 0.85 mm, 0.9 mm, 0.95 mm, 1 mm, 1.05 mm, 1.1 mm, 1.15 mm and 1.2 mm.

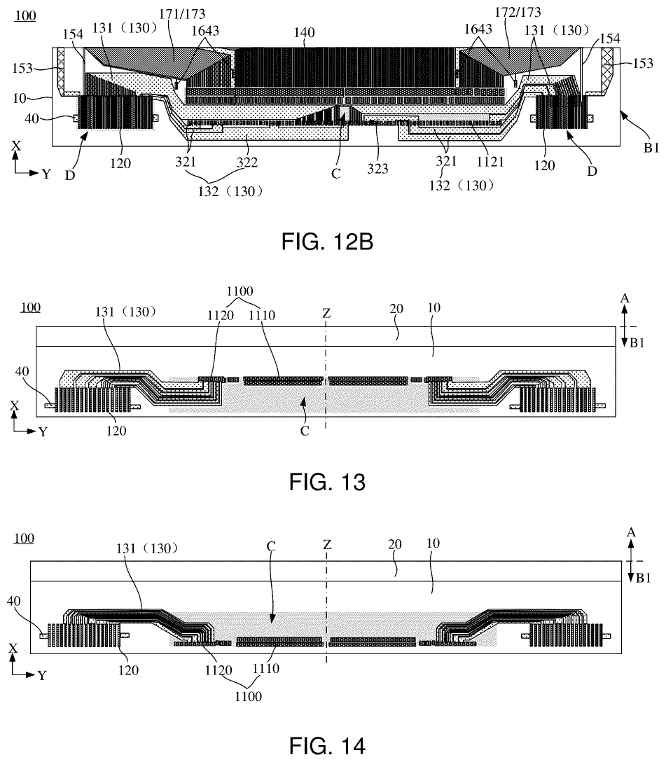

In addition, edges of the bonding areas D away from the display area A may be substantially flush with an edge of the chip setting area C away from the display area A. In this way, a distance between the bonding area D and the display area A may be made large without increasing a width of the first frame area B1 in the first direction X, which is convenient for providing wiring (e.g., peripheral connection lines 130 in FIG. 12A) or other circuit structures (e.g., first test pads 1641 in FIG. 18) between the bonding area D and the display area A.

In some embodiments, referring to FIGS. 4 and 5, an edge of the first frame area B1 of the array substrate 10 away from the display area A exceeds an edge of the color filter substrate 20 corresponding to the first frame area B1 in the first direction X, and an edge of the array substrate 10 away from the first frame area B1 and edges of the array substrate 10 in a second direction Y are approximately flush with respective edges of the color filter substrate 20. It will be noted that the second direction Y intersects the first direction X. For example, the second direction Y is substantially perpendicular to the first direction X.

For example, as shown in FIGS. 4 and 5, the peripheral area B may further include a second frame area B2, a third frame area B3, and a fourth frame area B4. The second frame area B2 is located on a side of the display area A away from the first frame area B1. In the second direction Y, the third frame area B3 and the fourth frame area B4 are located on opposite sides of the display area A.

The edges of the second frame area B2, the third frame area B3 and the fourth frame area B4 of the array substrate 10 are substantially flush with the respective edges of the color filter substrate 20.

In addition, referring to FIGS. 8 to 11, both the chip setting area C and the bonding areas D of the array substrate 10 may be located between the edge of the first frame area B1 of the array substrate 10 away from the display area A and the edge of the color filter substrate 20 corresponding to the first frame area B1, so as to facilitate connection between the flexible circuit board 400 (referring to FIG. 3) and the array substrate 10 and connection between the driver chip 500 (referring to FIG. 3) and the array substrate 10.

For example, a distance between the edge of the color filter substrate 20 corresponding to the first frame area B1 and the edge of the display area A proximate to the first frame area B1 is in a range of 0.9 mm to 2.5 mm, inclusive. For example, the distance between the edge of the color filter substrate 20 corresponding to the first frame area B1 and the edge of the display area A proximate to the first frame area B1 is any of 0.9 mm, 1 mm, 1.1 mm, 1.2 mm, 1.3 mm, 1.4 mm, 1.5 mm, 1.6 mm, 1.7 mm, 1.8 mm, 1.9 mm, 2 mm, 2.1 mm, 2.2 mm, 2.3 mm, 2.4 mm and 2.5 mm.

For example, a distance between the edge of the color filter substrate 20 corresponding to the first frame area B1 and an edge of the chip setting area C proximate to the display area A is in a range of 0.29 mm to 1.5 mm, inclusive. For example, the distance between the edge of the color filter substrate 20 corresponding to the first frame area B1 and the edge of the chip setting area C proximate to the display area A is any of 0.29 mm, 0.3 mm, 0.4 mm, 0.5 mm, 0.55 mm, 0.6 mm, 0.65 mm, 0.7 mm, 0.8 mm, 0.9 mm, 1 mm, 1.1 mm, 1.2 mm, 1.3 mm, 1.4 mm and 1.5 mm.

For example, a distance between the edge of the color filter substrate 20 corresponding to the first frame area B1 and an edge of the bonding area D proximate to the display area A is in a range of 0.49 mm to 2.35 mm, inclusive. For example, the distance between the edge of the color filter substrate 20 corresponding to the first frame area B1 and the edge of the bonding area D proximate to the display area A is any of 0.49 mm, 0.5 mm, 0.55 mm, 0.6 mm, 0.7 mm, 0.75 mm, 0.8 mm, 0.9 mm, 1 mm, 1.2 mm, 1.4 mm, 1.5 mm, 1.6 mm, 1.65 mm, 1.7 mm, 1.9 mm, 2 mm, 2.1 mm, 2.2 mm, 2.3 mm and 2.35 mm.

By taking an example where the peripheral area B includes the first frame area B1, the second frame area B2, the third frame area B3 and the fourth frame area B4, some embodiments of the present disclosure are schematically described below, but the embodiments of the present disclosure are not limited thereto.

Referring to FIGS. 6A and 6B, the array substrate 10 includes a first substrate 11, and a plurality of driving pads 110, a plurality of bonding pins 120 and a plurality of peripheral connection lines 130 disposed on the first substrate 11.

As shown in FIGS. 4, 6A and 8, all the driving pads 110 are provided in the chip setting area C, and the driving pads 110 are configured to be connected to the driver chip 500. That is, the driver chip 500 is provided with pins thereon, and the driver chip 500 is connected to the driving pads 110 by the pins.

As shown in FIGS. 4, 6A and 8, all the bonding pins 120 are provided in the bonding areas D, and the bonding pins 120 are configured to be connected to the flexible circuit boards 400. That is, the flexible circuit board 400 is provided with gold fingers thereon, and the flexible circuit board 400 is connected to bonding pins 120 by the gold fingers.

As shown in FIGS. 4, 6A and 12A, all the peripheral connection lines 130 are provided in the first frame area B1 and are located between the edge of the first frame area B1 of the array substrate 10 away from the display area A and the edge of the color filter substrate 20 corresponding to the first frame area B1.

An end of each peripheral connection line 130 is connected to a driving pad 110, and the other end of each peripheral connection line 130 is connected to a bonding pin 120, so that the flexible circuit board 400 is connected to the driver chip 500, thereby providing various signals required to the driver chip 500 and the display panel 100.

In the related art, the bonding pins are located on a side of the driving pads away from the display area, that is, the bonding area is located on a lower side of the chip setting area. With such provision, the width of the first frame area in the first direction has a relatively large design requirement, which is not conducive to a narrow frame design of the display device.

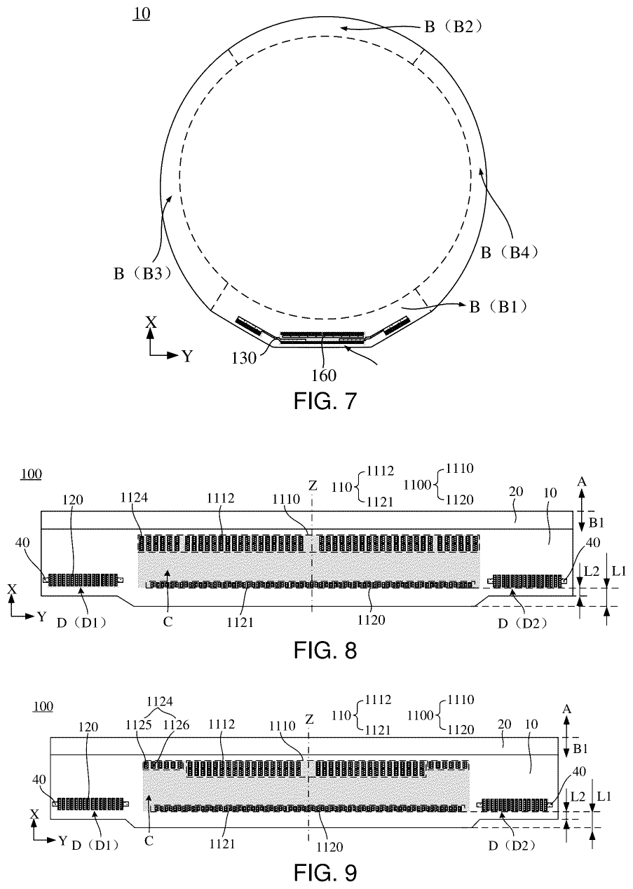

In light of this, referring to FIGS. 7 to 11, some embodiments of the present disclosure provide an array substrate 10 in which the bonding areas D are located on at least one side of the chip setting area C in the second direction Y.

That is, in the first frame area B1, the bonding pins 120 are disposed in areas on both sides of all the driving pads 110 in the second direction Y. In this way, it may avoid an increase in the width of the first frame area B1 in the first direction X, thereby shortening a lower frame (referring to FIG. 1) of the display device and increasing a screen-to-body ratio.

For example, as shown in FIGS. 7 to 11, in the second direction Y, the bonding areas D are located on opposite sides of the chip setting area C, that is, the plurality of bonding pins 120 are disposed on opposite sides of all the driving pads 110.

For example, as shown in FIGS. 7 to 11, the bonding areas D include a first bonding area D1 and a second bonding area D2. In the second direction Y, the first bonding area D1 and the second bonding area D2 are respectively located on the opposite sides of the chip setting area C. That is, the plurality of bonding pins 120 may be respectively disposed in the first bonding area D1 and the second bonding area D2. Moreover, the plurality of bonding pins 120 may be symmetrically disposed on the opposite sides of all the driving pads 110.

On this basis, as shown in FIGS. 7 to 14, the array substrate 10 has an axis Z extending in the first direction X. The plurality of driving pads 110, the plurality of bonding pins 120 and the plurality of peripheral connection lines 130 are each arranged symmetrically about the axis Z, so as to simplify the circuit structure, improve the regularity of the circuit wiring, and reduce the preparation cost. Of course, the plurality of driving pads 110, the plurality of bonding pins 120 and the plurality of peripheral connection lines 130 may each be arranged not symmetrically about the axis Z. For example, the numbers of driving pads 110, bonding pins 120 and peripheral connection lines 130 located on a side of the axis Z are respectively greater than the numbers of driving pads 110, bonding pins 120 and peripheral connection lines 130 located on the other side of the axis Z.

In this case, referring to FIGS. 4, 5 and 8, the display device 1000 includes two flexible circuit boards 400. The two flexible circuit boards 400 are respectively connected to the bonding pins 120 in the first bonding area D1 and the bonding pins 120 in the second bonding area D2. With such provision, it may not only avoid an increase in the width of the first frame area B1 in the first direction X, thereby shortening the lower frame of the display device 1000, but also facilitate wiring of the peripheral connection lines 130, which is conducive to reduction of the wiring width occupied by all the peripheral connection lines 130 in the first direction X.

In some embodiments, referring to FIGS. 5 and 8, the array substrate 10 may further include alignment marks 40. In the second direction Y, the alignment marks 40 are disposed on opposite sides of the bonding area D, so as to facilitate alignment connection between the flexible circuit board 400 and the bonding pins 120 in the bonding area D.

It will be noted that an orthographic projection of the alignment mark 40 on the first substrate 11 may be in a cross shape, a T shape, a quadrilateral shape, or a circular shape, and the embodiment of the present disclosure are not specifically limited thereto.

In some embodiments, referring to FIGS. 6B, 8 and 12A, the plurality of peripheral connection lines 130 include first peripheral connection lines 131. The first peripheral connection lines 131 extend to a side of the chip setting area C proximate to the bonding area D in the chip setting area C. Moreover, an end of the first peripheral connection line 131 is connected to a driving pad 110 in the chip setting area C, and the other end of the first peripheral connection line 131 is connected to a bonding pin 120 in the bonding area D.

It will be noted that in a case where the first frame area B1 includes two bonding areas D, an end of the first peripheral connection line 131 is connected to the driving pad 110, and the other end of the first peripheral connection line 131 extends to a side of the chip setting area C proximate to a bonding area D closer to the chip setting area C in the two bonding areas D, and is connected to bonding pins 120 in the bonding area D closer to the chip setting area C.

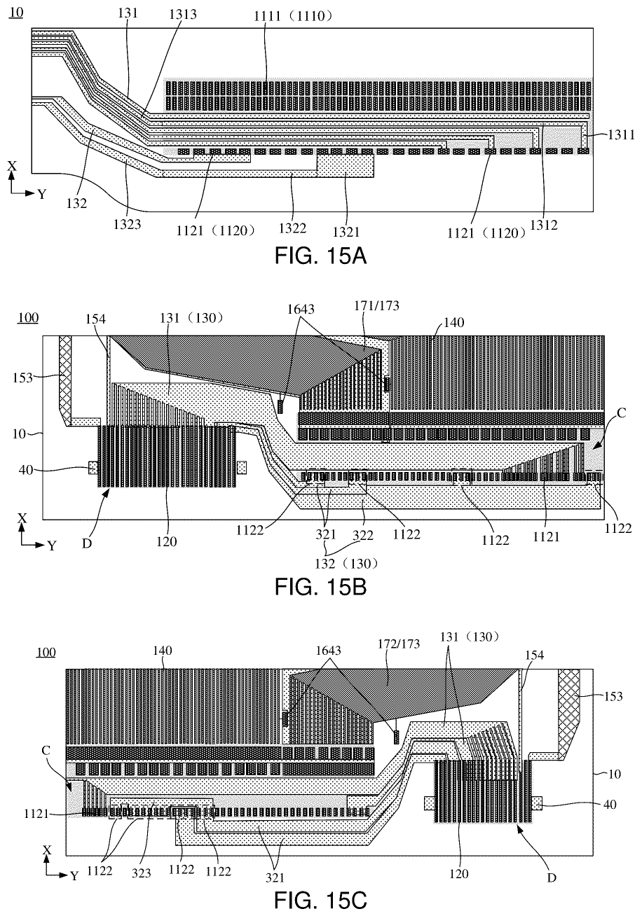

For example, as shown in FIGS. 6B and 15A, the first peripheral connection line 131 includes a first line segment 1311, a second line segment 1312 and a first connection line segment 1313 that are connected in sequence. The first line segment 1311 is connected to the driving pad 110, and the first connection line segment 1313 is connected to the bonding pin 120.

As shown in FIGS. 6B, 8 and 15A, the first line segment 1311 is disposed in the chip setting area C and extends generally in the first direction X. The second line segment 1312 is disposed in the chip setting area C, and extends to a side of the chip setting area C proximate to the bonding area D generally in the second direction Y.

In this case, in the first direction X, a portion of the first peripheral connection line 131 overlapped with the chip setting area C may be routed inside the chip setting area C, thereby avoiding an increase in the width of the first frame area B1 in the first direction X caused by routing outside the chip setting area C.

It can be understood that as shown in FIGS. 8 to 11, the plurality of driving pads 110 are arranged into a plurality of driving pad groups 1100, and the plurality of driving pad groups 1100 include an output pad group 1110 and input pad group(s) 1120.

As shown in FIGS. 8 to 14, the output pad group 1110 includes a plurality of output pads 1111 arranged in the second direction Y, and the input pad group 1120 includes a plurality of input pads 1121 arranged in the second direction Y. Moreover, an end of the first peripheral connection line 131 is connected to input pad(s) 1121, and the other end of the first peripheral connection line 131 is connected to bonding pin(s) 120.

On this basis, in the second direction Y, the input pad group(s) 1120 are located on at least one side of the output pad group 1110. Alternatively, the input pad group 1120 is located on a side of the output pad group 1110 away from the display area A.

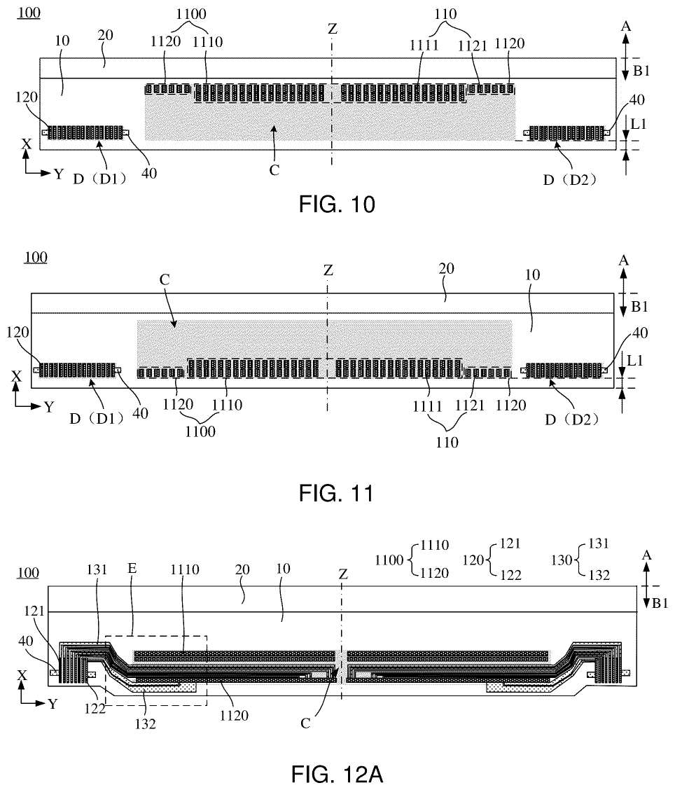

In some embodiments, as shown in FIGS. 10 and 11, the input pad group(s) 1120 are located on at least one side of the output pad group 1110 in the second direction Y.

For example, as shown in FIGS. 10 and 11, the bonding areas D include a first bonding area D1 and a second bonding area D2. In the second direction Y, the first bonding area D1 and the second bonding area D2 are located on opposite sides of the chip setting area C. In this case, the plurality of input pads 1121 may be symmetrically arranged on opposite sides of the output pad group 1110.

For example, as shown in FIG. 10, an edge of the plurality of driving pad groups 1100 proximate to the display area A substantially coincides with an edge of the chip setting area C proximate to the display area A.

On this basis, referring to FIGS. 10 and 13, all the peripheral connection lines 130 may be first peripheral connection lines 131. First peripheral connection lines 131 extend to a side of the chip setting area C proximate to the bonding area D at a side of the plurality of driving pad groups 1100 away from the display area A. Moreover, ends of the first peripheral connection lines 131 are connected to an end of the input pad group 1120 away from the display area A, and the other ends of the first peripheral connection lines 131 are connected to ends of bonding pins 120 proximate to the display area A.

In this way, a distance between the chip setting area C and the edge of the first frame area B1 away from the display area A and a distance between the bonding area D and the edge of the first frame area B1 away from the display area A may be designed to be extremely small.

For example, the distance between the chip setting area C and the edge of the first frame area B1 away from the display area A is in a range of 0.07 mm to 0.2 mm, inclusive. For example, the distance between the chip setting area C and the edge of the first frame area B1 away from the display area A is any of 0.07 mm, 0.08 mm, 0.09 mm, 0.1 mm, 0.12 mm, 0.15 mm, 0.18 mm and 0.2 mm.

For example, the distance between the bonding area D and the edge of the first frame area B1 away from the display area A is in a range of 0.07 mm to 0.2 mm, inclusive. For example, the distance between the bonding area D and the edge of the first frame area B1 away from the display area A is any of 0.07 mm, 0.08 mm, 0.09 mm, 0.1 mm, 0.12 mm, 0.15 mm, 0.18 mm and 0.2 mm.

As another example, as shown in FIG. 11, an edge of the plurality of driving pad groups 1100 away from the display area A substantially coincides with an edge of the chip setting area C away from the display area A.

On this basis, referring to FIGS. 11 and 14, all the peripheral connection lines 130 may be first peripheral connection lines 131. First peripheral connection lines 131 extend to a side of the chip setting area C proximate to the bonding area D at a side of the plurality of driving pad groups 1100 proximate to the display area A. Moreover, ends of the first peripheral connection lines 131 are connected to an end of the input pad group 1120 proximate to the display area A, and the other ends of the first peripheral connection lines 131 are connected to ends of bonding pins 120 proximate to the display area A.

In this way, there is no circuit wiring on a side of both the chip setting area C and the bonding area D away from the display area A. That is, a distance between the chip setting area C and the edge of the first frame area B1 away from the display area A and a distance between the bonding area D and the edge of the first frame area B1 away from the display area A may be designed to be extremely small.

For example, the distance between the chip setting area C and the edge of the first frame area B1 away from the display area A is in a range of 0.07 mm to 0.2 mm, inclusive. For example, the distance between the chip setting area C and the edge of the first frame area B1 away from the display area A is any of 0.07 mm, 0.08 mm, 0.09 mm, 0.1 mm, 0.12 mm, 0.15 mm, 0.18 mm and 0.2 mm.

For example, the distance between the bonding area D and the edge of the first frame area B1 away from the display area A is in a range of 0.07 mm to 0.2 mm, inclusive. For example, the distance between the bonding area D and the edge of the first frame area B1 away from the display area A is any of 0.07 mm, 0.08 mm, 0.09 mm, 0.1 mm, 0.12 mm, 0.15 mm, 0.18 mm and 0.2 mm.

In some other embodiments, as shown in FIGS. 8 and 9, the input pad group 1120 is located on a side of the output pad group 1110 away from the display area A.

On this basis, referring to FIGS. 8, 9 and 12A, first peripheral connection lines 131 extend to a side of the chip setting area C proximate to the bonding area D between the input pad group 1120 and the output pad group 1110. Moreover, ends of the first peripheral connection lines 131 are connected to ends of input pads 1121 proximate to the output pad group 1110, and the other ends of the first peripheral connection lines 131 are connected to ends of bonding pins 120 proximate to the display area A.

Here, a distance between the first peripheral connection line 131 and the output pad group 1110 is greater than or equal to 20 μm, so as to avoid the risk of crushing the first peripheral connection line 131 during bonding the driver chip 500.

By taking an example where the input pad group 1120 is located on a side of the output pad group 1110 away from the display area A, some embodiments of the present disclosure are schematically described below, but the embodiments of the present disclosure are not limited thereto.

It can be understood that, referring to FIGS. 6B, 8, 12A and 15A, in the chip setting area C, in a case where it is impossible to make all the peripheral connection lines 130 extend to a side of the chip setting area C proximate to the bonding area D in the chip setting area C, the plurality of peripheral connection lines 130 further include second peripheral connection lines 132.

The second peripheral connection lines 132 extend to a side of the chip setting area C proximate to the bonding area D at a side of the chip setting area C away from the display area A. Moreover, an end of the second peripheral connection line 132 is connected to ends of input pads 1121 away from the output pad group 1110, and the other end of the second peripheral connection line 132 is connected to end(s) of bonding pin(s) 120 in the bonding area D proximate to the display area A.

In some embodiments, referring to FIGS. 15B and 15C, the input pad group 1120 includes a plurality of input pad sub-groups 1122, and the input pad sub-group 1122 includes a plurality of input pads 1121 that are adjacently arranged and transmit the same signal.

In this case, as shown in FIGS. 12B, 15B and 15C, a plurality of second peripheral connection lines 132 include first type of second peripheral connection line(s) 321 and second type of second peripheral connection line(s) 322. The first type of second peripheral connection line 321 is connected to bonding pins 120 and a single input pad sub-group 1122. The second type of second peripheral connection line 322 is connected to bonding pins 120 and at least two input pad sub-groups 1122, and the second type of second peripheral connection line 322 is located on a side of the first type of second peripheral connection line 321 away from the display area A.

For example, as shown in FIG. 12B, in the second direction Y, the bonding areas D are located on opposite sides of the chip setting area C, that is, the first frame area B1 includes two bonding areas D.

In this case, as shown in FIGS. 12B and 15B, the plurality of second peripheral connection lines 132 may include, for example, two first type of second peripheral connection lines 321 and a second type of second peripheral connection line 322. The two first type of second peripheral connection lines 321 are each connected to an input pad sub-group 1122 and bonding pins 120 on the first side (e.g., a left side in FIG. 12B) of the chip setting area C. The two first type of second peripheral connection lines 321 are provided away from the display area A in sequence. The second type of second peripheral connection line 322 is connected to bonding pins 120 on the first side (e.g., a left side in FIG. 12B) of the chip setting area C and two input pad sub-groups 1122. Moreover, the second type of second peripheral connection line 322 is located on a side of the two first type of second peripheral connection lines 321 away from the display area A.

In some embodiments, as shown in FIGS. 12B and 15C, the array substrate 10 further includes an input transfer line 323. The input transfer line 323 is provided in the chip setting area C and is connected to at least two input pad sub-groups 1122. In at least two input pad sub-groups 1122, an input pad sub-group 1122 is also connected to a second peripheral connection line 132.

For example, as shown in FIG. 12B, in the second direction Y, the bonding areas D are located on opposite sides of the chip setting area C, that is, the first frame area B1 includes two bonding areas D.

In this case, as shown in FIGS. 12B and 15C, the plurality of second peripheral connection lines 132 include two first type of second peripheral connection lines 321. The two first type of second peripheral connection lines 321 are each connected to an input pad sub-group 1122 and bonding pins 120 on the second side (e.g., a right side in FIG. 12B) of the chip setting area C. The two first type of second peripheral connection lines 321 are provided away from the display area A in sequence.

On this basis, as shown in FIGS. 12B and 15C, the array substrate 10 further includes an input transfer line 323, and the input transfer line 323 is connected to three input pad sub-groups 1122. In the three input pad sub-groups 1122, two input pad sub-groups 1122 and one input pad sub-group 1122 are respectively located on opposite sides of an input pad sub-group 1122 connected to a first type of second peripheral connection line 321 further away from the display area A in the above two first type of second peripheral connection lines 321, and the one input pad sub-group 1122 is connected to another first type of second peripheral connection line 321 closer to the display area A in the above two first type of second peripheral connection lines 321.

The above second peripheral connection line 132 may transmit a signal with high requirements for resistance, so that the width of the second peripheral connection line 132 increases and the resistance is reduced. For example, the second peripheral connection line 132 transmits a common voltage signal.

It will be noted that in a case where the first frame area B1 includes two bonding areas D, an end of the second peripheral connection line 132 is connected to driving pads 110, and the other end of the second peripheral connection line 132 extends to a side of the chip setting area C proximate to a bonding area D closer to the chip setting area C in the two bonding areas D, and is connected to bonding pins 120 in the bonding area D closer to the chip setting area C.

For example, as shown in FIGS. 6B, 8 and 15A, the second peripheral connection line 132 includes a third line segment 1321, a fourth line segment 1322 and a second connection line segment 1323 that are connected in sequence. The third line segment 1321 is connected to the driving pad 110, and the second connection line segment 1323 is connected to the bonding pins 120. The third line segment 1321 is disposed in the chip setting area C and extends generally in the first direction X. The fourth line segment 1322 is disposed in the chip setting area C, and extends to a side of the chip setting area C proximate to the bonding area D generally in the second direction Y.

In this case, among all the peripheral connection lines 130, some of the peripheral connection lines 130 (i.e., the first peripheral connection lines 131) extend to a side of the chip setting area C proximate to the bonding area D in the chip setting area C, so as to shorten the first frame area B1; and some other of the peripheral connection lines 130 (i.e., the second peripheral connection lines 132) extend to a side of the chip setting area C proximate to the bonding area D at a side of the chip setting area C away from the display area A, so as to avoid interference with other circuits or driving pads 110 in the chip setting area C.

On this basis, referring to FIGS. 8 and 9, a distance between the chip setting area C and a first edge is a first distance L1, and a distance between the bonding area D and the first edge is a second distance L2. The first edge is an edge of the first frame area B1 of the array substrate 10 away from the display area A.

As shown in FIGS. 8 and 9, the first distance L1 may be greater than the second distance L2. For example, a difference between the first distance L1 and the second distance L2 is in a range of 0.3 mm to 0.6 mm, inclusive. For example, the difference between the first distance L1 and the second distance L2 is any of 0.3 mm, 0.35 mm, 0.4 mm, 0.45 mm, 0.5 mm, 0.55 mm and 0.6 mm.

In some embodiments, as shown in FIGS. 12A and 15A, the bonding pin 120 connected to the first peripheral connection line 131 is the first bonding pin 121. The bonding pin 120 connected to the second peripheral connection line 132 is the second bonding pin 122.

The first bonding pin 121 is further away from the chip setting area C than the second bonding pin 122, and the second peripheral connection line 132 is located on a side of the first peripheral connection line 131 away from the display area A. With such provision, the first peripheral connection line 131 and the second peripheral connection line 132 may be disposed in a staggered manner, thereby simplifying the circuit wiring arrangement. Furthermore, the first peripheral connection line 131 and the second peripheral connection line 132 are disposed in the same layer and made of the same material, thereby reducing the manufacturing cost.

It will be understood that during manufacturing the display device, after circuits and signal lines in the array substrate 10 are manufactured, a test circuit is required to detect the circuits and signal lines in the array substrate 10 to determine whether a short circuit or an open circuit exists in the array substrate 10.

Based on this, referring to FIGS. 6A and 6B, the array substrate 10 further includes a plurality of sub-pixels P, a plurality of data lines 140, a plurality of scan lines 150 and a test circuit 160.

As shown in FIGS. 4 and 5, the sub-pixels P are provided in the display area A.

As shown in FIGS. 5, 16 and 17, the sub-pixel P includes a pixel circuit 21, a pixel electrode 22 and a common electrode 23. The pixel circuit 21 includes a thin film transistor 210. The thin film transistor 210 includes an active layer 211, a source 212, a drain 213, and a gate 214. The source 212 and the drain 213 are in contact with the active layer 211.

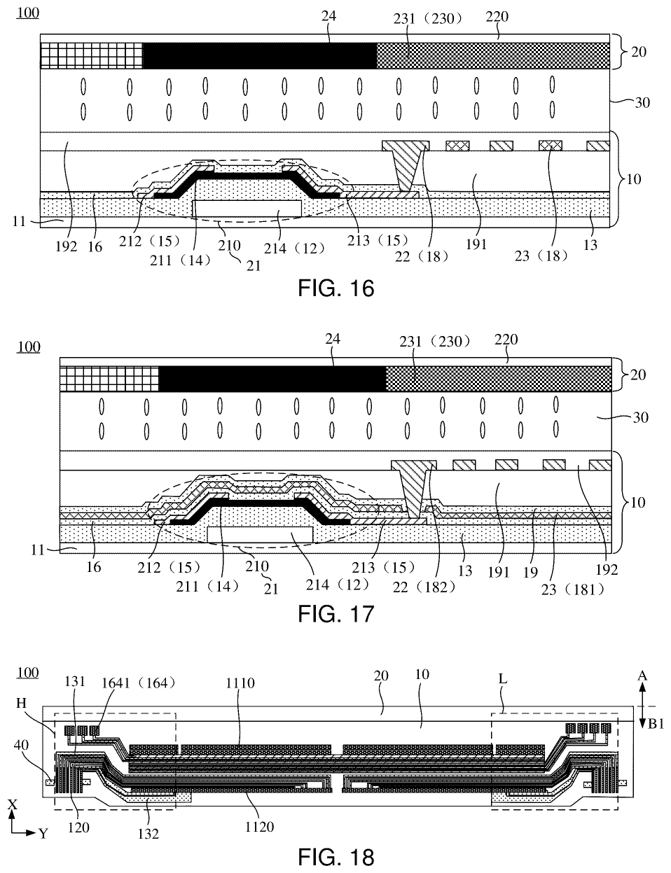

In this case, the pixel electrode 22 may be electrically connected to the source 212 or the drain 213 of the thin film transistor 210. FIGS. 16 and 17 illustrate an example in which the pixel electrode 22 is electrically connected to the drain 213 of the transistor 210.

In addition, the pixel electrode 22 and the common electrode 23 are spaced apart, and an electric field is generated between the pixel electrode 22 and the common electrode 23 to deflect the liquid crystal molecules in the liquid crystal layer 30.

It will be noted that the pixel electrode 22 and the common electrode 23 may be provided in the same layer and made of the same material, or may be located in different layers. For details, reference may be made to the following context, and the embodiments of the present disclosure will not provide details here.

In some embodiments, as shown in FIGS. 6A and 6B, the plurality of sub-pixels P may be arranged, for example, in a plurality of rows and a plurality of columns. Each row of sub-pixels P may include multiple sub-pixels P arranged in the second direction Y. Each column of sub-pixels P may include multiple sub-pixels P arranged in the first direction X.

It will be noted that in this text, definitions of rows and columns are relative concepts, and rows and columns respectively represent two different extension directions of the array arrangement.

For ease of description, multiple sub-pixels P arranged in a line in the second direction Y are referred to as sub-pixels P in a same row, and multiple sub-pixels P arranged in a line in the first direction X are referred to as sub-pixels P in a same column.

As shown in FIGS. 6A and 6B, the plurality of data lines 140 are connected to the plurality of sub-pixels P. For example, the plurality of data lines 140 extend in the first direction X, and each data line 140 is connected to pixel circuits 21 of sub-pixels P in a column. Moreover, in combination with FIG. 8, the above output pad group 1110 includes data output pads 1112, and the data line 140 is also connected to a data output pad 1112 to receive a data signal output by the driver chip 500 (referring to FIG. 3) or a data signal output by an external circuit.

As shown in FIGS. 6A and 6B, the plurality of scan lines 150 are connected to the plurality of sub-pixels P. For example, the plurality of scan lines 150 extend in the second direction Y, and each scan line 150 is connected to pixel circuits 21 of sub-pixels P in a row. Moreover, in combination with FIG. 8, the above output pad group 1110 includes a plurality of scan output pads 1124, and the scan line 150 is also connected to a scan output pad 1124 to receive a scan signal output by the driver chip 500 or a scan signal output by an external circuit.

As shown in FIGS. 6A and 6B, the test circuit 160 is connected to the plurality of data lines 140, the plurality of scan lines 150 and the plurality of sub-pixels P. The test circuit 160 is configured to receive test signals transmitted by the external circuit in a test phase to detect the circuits and signal lines in the array substrate 10.

For example, referring to FIGS. 6A, 18, 19 and 22 to 25, the test circuit 160 includes a first test circuit 161, a second test circuit 162 and a first test signal line 163.

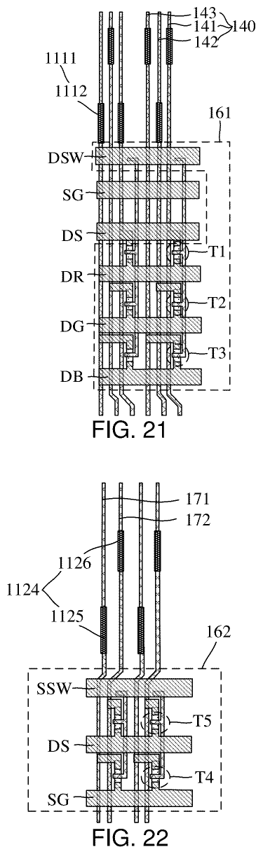

As shown in FIG. 21, the first test circuit 161 is connected to multiple data lines 140. The first test circuit 161 is configured to receive data signals transmitted by the external circuit in the test phase.

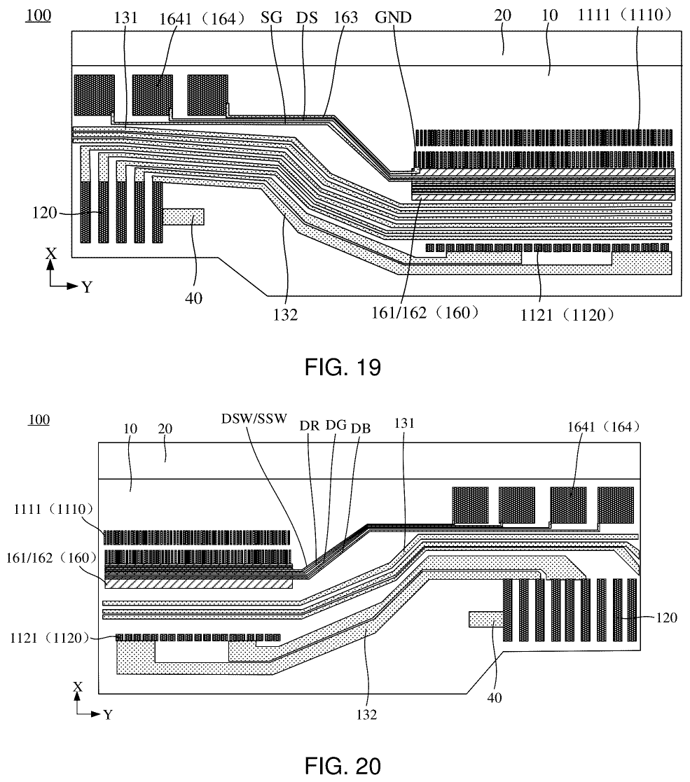

In a case where an area of an idle region in the chip setting area C is relatively large and the first test circuit 161 may also be provided in the chip setting area C, referring to FIGS. 19 and 21, the first test circuit 161 is provided between the input pad group 1120 and the output pad group 1110, and is connected to the data output pads 1112 and thus connected to the data lines 140.

It will be noted that the “idle region” refers to a region without any circuit structures (e.g., the driving pads 110) or any circuit wiring (e.g., the peripheral connection lines 130) provided.

In a case where the area of the idle region in the chip setting area C is relatively small and the first test circuit 161 cannot be provided in the chip setting area C, as shown in FIG. 6B, the first test circuit 161 may be provided in the second frame area B2 and connected to the multiple data lines 140.

In some embodiments, as shown in FIGS. 6A and 21, the plurality of sub-pixels P include first sub-pixels, second sub-pixels and third sub-pixels for emitting light of different colors. The plurality of data lines 140 include a first data line 141, a second data line 142 and a third data line 143. The first data line 141 is connected to a first sub-pixel, the second data line 142 is connected to a second sub-pixel, and the third data line 143 is connected to a third sub-pixel.

On this basis, as shown in FIG. 21, the first test circuit 161 includes a first data test line DR, a second data test line DB, a third data test line DG, first transistors T1, second transistors T2, third transistors T3 and a first switch signal line DSW.

As shown in FIG. 21, the first data test line DR is configured to transmit a data signal for allowing the first sub-pixel to emit light, the second data test line DB is configured to transmit a data signal for allowing the second sub-pixel to emit light, and the third data test line DG is configured to transmit a data signal for allowing the third sub-pixel to emit light.

In addition, as shown in FIG. 21, a first electrode of the first transistor T1 is connected to the first data test line DR, and a second electrode of the first transistor T1 is connected to the first data line 141. A first electrode of the second transistor T2 is connected to the second data test line DB, and a second electrode of the second transistor T2 is connected to the second data line 142. A first electrode of the third transistor T3 is connected to the third data test line DG, and a second electrode of the third transistor T3 is connected to the third data line 143. Moreover, the first switch signal line DSW is connected to gates of the first transistor T1, the second transistor T2 and the third transistor T3, so as to control on or off of the first data test line DR and the first data line 141, on or off of the second data test line DB and the second data line 142, and on or off of the third data test line DG and the third data line 143.

With such provision, as shown in FIG. 21, the first test circuit 161 includes the first data test line DR, the second data test line DB, the third data test line DG and the first switch signal line DSW, so that the data signals transmitted by the external circuit may be received. Thus, the first sub-pixel, the second sub-pixel and the third sub-pixel may be allowed to emit light to detect the circuit and signal lines in the array substrate 10. The structure is simple and the manufacturing cost is low.

That is, as shown in FIGS. 18, 19 and 20, in a case where the test circuit 160 further includes test pads 164 and the test circuit 160 is connected to the external circuit by the test pads 164 to receive test signals input from the external circuit, the first test circuit 161 is connected to four test pads 164 to receive the required data signals. In this way, the number of the test pads 164 may be reduced, which may facilitate providing the test pads 164 in the idle region of the array substrate 10, thereby simplifying the process flow and reducing the manufacturing cost.

As shown in FIGS. 19, 20 and 22, the second test circuit 162 is connected to multiple scan lines 150 (referring to FIG. 6A). The second test circuit 162 is configured to receive scan signals transmitted by the external circuit in the test phase.

In some embodiments, referring to FIGS. 6A and 22, the scan lines 150 includes first scan lines 151 and second scan lines 152. The plurality of scan output pads 1124 include a plurality of first scan output pads 1125 and a plurality of second scan output pads 1126.

The first scan line 151 is connected to sub-pixels P in an odd row, and the second scan line 152 is connected to sub-pixels P in an even row. Moreover, the array substrate 10 further includes first scan connection lines 171 and second scan connection lines 172. The first scan connection line 171 is connected to a first scan line 151 and a first scan output pad 1125. The second scan connection line 172 is connected to a second scan line 152 and a second scan output pad 1126.

On this basis, as shown in FIG. 22, the second test circuit 162 includes a first scan test line SG, a second scan test line DS, fourth transistors T4, fifth transistors T5 and a second switch signal line SSW. The first scan test line SG is configured to transmit a scan signal for allowing sub-pixels P in an odd row to emit light. The second scan test line DS is configured to transmit a scan signal for allowing sub-pixels P in an even row to emit light.

A first electrode of the fourth transistor T4 is connected to the first scan test line SG, and a second electrode of the fourth transistor T4 is connected to a first scan output pad 1125. A first electrode of the fifth transistor T5 is connected to the second scan test line DS, and a second electrode of the fifth transistor T5 is connected to a second scan output pad 1126. The second switch signal line SSW is connected to gates of the fourth transistor T4 and the fifth transistor T5.

It will be noted that, as shown in FIGS. 21 and 22, the second switch signal line SSW and the first switch signal line DSW may be the same signal line, thereby simplifying the circuit structure and reducing the manufacturing cost.

With such provision, as shown in FIGS. 19 and 22, the second test circuit 162 includes the first scan test line SG and the second scan test line DS, so that the scan signals transmitted by the external circuit may be received. Thus, the first sub-pixel, the second sub-pixel and the third sub-pixel may be allowed to emit light to detect the circuit and signal lines in the array substrate 10. The structure is simple and the manufacturing cost is low.

That is, as shown in FIGS. 19 and 22, in a case where the test circuit 160 further includes test pads 164 and the test circuit 160 is connected to the external circuit by the test pads 164 to receive test signals input from the external circuit, the second test circuit 162 is connected to two test pads 164 to receive the required scan signals. In this way, the number of the test pads 164 may be reduced, which may facilitate providing the test pads 164 in the idle region of the array substrate 10, thereby simplifying the process flow and reducing the manufacturing cost.

In some other embodiments, referring to FIG. 6B, the array substrate 10 includes gate driver circuits 180 and gate control signal lines 173. The gate driver circuit 180 is disposed in the third frame area B3 or the fourth frame area B4.

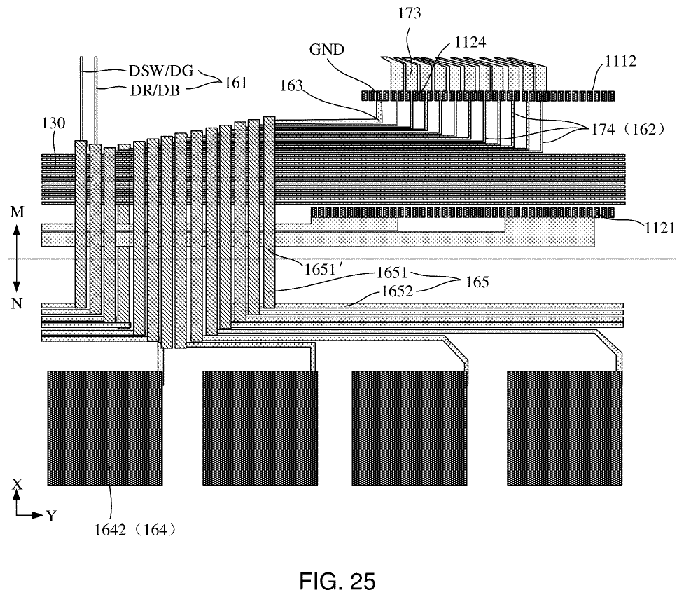

In combination with FIGS. 6B and 25, the gate driver circuit 180 is connected to multiple scan lines 150, and the gate control signal line 173 is connected to the gate driver circuit 180 and the scan output pad 1124.

On this basis, the second test circuit 162 includes a plurality of gate control test lines 174, and the gate control test lines 174 are respectively connected to the scan output pads 1124. Moreover, the gate control test line 174 is configured to transmit a gate control signal for allowing sub-pixels P to emit light.

With such provision, as shown in FIGS. 6B and 25, in a case where the test circuit 160 further includes test pads 164 and the test circuit 160 is connected to the external circuit by the test pads 164 to receive test signals input from the external circuit, a scan output pad 1124 connected to each gate control test line 174 need to be connected to a corresponding test pad 164.

As shown in FIGS. 6B, 16 and 19, the first test signal line 163 is connected to the common electrode 23 of the plurality of sub-pixels P. The first test signal line 163 is configured to transmit a common voltage signal.

The plurality of driving pads 110 include a common voltage pad GND. The common voltage pad GND is connected to the common electrode 23 of the plurality of sub-pixels P. The first test signal line 163 is connected to the common voltage pad GND. Here, as shown in FIGS. 12A and 19, the common voltage pad GND may be located in the input pad group 1120 or the output pad group 1110.

It can be understood that the test circuit 160 further includes the test pads 164 to be connected to the external circuit to receive test signals input from the external circuit. Here, the test pads 164 may be disposed in the array substrate 10, or may be disposed outside the array substrate 10. After the detection is completed, the outer portion of the array substrate 10 is cut.

Referring to FIGS. 6A, 19 and 20, in a case where the array substrate 10 includes the first scan connection lines 171 and the second scan connection lines 172, and the second test circuit 162 includes the first scan test line SG and the second scan test line DS, the number of the test pads 164 is greater than or equal to 7.

For example, as shown in FIGS. 6A and 18 to 20, there are seven test pads 164, where four test pads 164 are connected to the first test circuit 161, two test pads are connected to the second test circuit 162, and one test pad 164 is connected to the first test signal line 163. In this case, the number of the test pads 164 is relatively small, which may facilitate providing the test pads 164 in the idle region of the array substrate 10, thereby simplifying the process flow and reducing the manufacturing cost.

Referring to FIGS. 6B, 23 and 24, in a case where the array substrate 10 includes the gate driver circuits 180 and the gate control signal lines 173, and the second test circuit 162 includes the plurality of gate control test lines 174, the number of the test pads 164 is in a range of 20 to 40, inclusive. For example, the number of the test pads 164 is in a range of 26 to 32, inclusive.

For example, as shown in FIG. 24, there are twenty-eight test pads 164, where four test pads 164 are connected to the first test circuit 161, twenty-three test pads are connected to the second test circuit 162, and one test pad 164 is connected to the first test signal line 163. In this case, the gate driver circuits 180 are disposed in the third frame area B3 and/or the fourth frame area B4 of the array substrate 10, so that an area of the chip setting area C may be reduced, thereby reducing an area of the first frame area B1, which is beneficial to the narrow frame design of the display device 1000.

Some embodiments of the present disclosure provide an array substrate 10. As shown in FIGS. 6B and 18, the test circuit 160 further includes first test pads 1641. The first test pads 1641 are disposed between the plurality of peripheral connection lines 130 and the display area A. For example, the first test pads 1641 are disposed between the plurality of peripheral connection lines 130 and an edge of the color filter substrate 20 proximate to the first frame area B1, so as to facilitate being connected to the external circuit.

The first test circuit 161, the second test circuit 162, and the first test signal line 163 are connected to the first test pads 1641.

Some embodiments of the present disclosure provide an array substrate 10. As shown in FIG. 12B, the array substrate 10 further includes third test pads 1643. The third test pads 1643 are disposed in the first frame area B1, and a third test pad 1643 is connected to a data line 140 or a scan line 150 (referring to FIG. 6B) to test whether the voltage of the scan signal or the voltage of the data signal is accurate.

As shown in FIGS. 6B and 12B, a third test pad 1643 connected to a data line 140 may be disposed between the data line 140 and the gate control signal line 173. A third test pad 1643 connected to a scan line 150 may be disposed between the peripheral connection line 130 and the gate control signal line 173.

In some embodiments, referring to FIGS. 6B and 12B, the array substrate 10 further includes an anti-static line 153 and a shielding line 154. The shielding line 154 is located on a side of the anti-static line 153 proximate to the display area A.

Referring to FIGS. 6B and 12B, the anti-static line 153 bypasses the second frame area B2, the third frame area B3 and the fourth frame area B4 to be connected to bonding pins 120 on both sides of the first frame area B1, so as to conduct away static electricity from the color filter substrate 20.

Referring to FIGS. 6B and 12B, the shielding line 154 bypasses the second frame area B2, the third frame area B3 and the fourth frame area B4 to be connected to bonding pins 120 on both sides of the first frame area B1, so as to achieve the effect of shielding external electromagnetic interference.

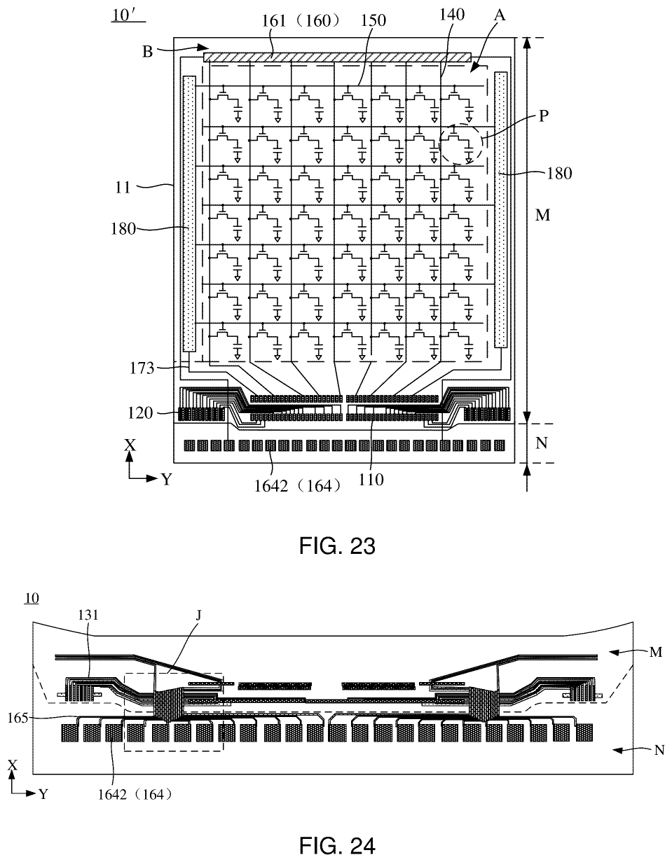

It will be understood that during manufacturing the array substrate 10, a whole of the array motherboard 10′ (referring to FIG. 23) is manufactured and then is cut to further complete the subsequent processes, thereby improving the manufacturing efficiency of the array substrate 10 and reducing the manufacturing cost.

Based on this, as shown in FIG. 23, some embodiments of the present disclosure provide an array motherboard 10′ having a plurality of product areas M and a plurality of areas N to be cut. Every two adjacent product areas M have an area N to be cut therebetween.

FIG. 23 is illustrated by taking an example of a product area M and an area N to be cut arranged in the first direction X.

As shown in FIG. 23, the product area M is an area of the array motherboard 10′ where the array substrate 10 (referring to FIG. 6B) is located. The area N to be cut is an area of the array motherboard 10′ that needs to be cut after the circuit detection is completed, that is, an area outside the array substrate 10 (referring to FIG. 6B).

Referring to FIGS. 23 and 24, the array motherboard 10′ includes second test pads 1642 and a plurality of test leads 165. The second test pad 1642 is disposed in the area N to be cut, and the plurality of test leads 165 are disposed in the area N to be cut.

Here, the plurality of test leads 165 are connected to the second test pads 1642 and a plurality of residual transfer lines 1651′, so that the second test pad 1642 is connected to the first test circuit 161, the second test circuit 162 and the first test signal line 163.

On this basis, as shown in FIG. 25, the test leads 165 may each include a cut-off transfer line 1651 and a test connection line 1652. The cut-off transfer line 1651 is connected to a residual transfer line 1651′, and the test connection line 1652 is connected to a cut-off transfer line 1651 and a second test pad 1642.

In this case, the cut-off transfer lines 1651 are located between the bonding area D and the chip setting area C, and extend in the first direction X. Moreover, the cut-off transfer line 1651 and the residual transfer line 1651′ may be, for example, made of the same material and arranged in the same layer, thereby reducing the manufacturing cost.

In this case, a portion of the array motherboard 10′ located in the area N to be cut is cut to form the array substrate 10. The cut-off transfer line 1651 is cut off, and a portion remaining in the array substrate 10 is the residual transfer line 1651′.

That is, in the array substrate 10, the test circuit 160 includes a plurality of residual transfer lines 1651′, and the residual transfer lines 1651′ are provided between the bonding area D and the chip setting area C. Moreover, the residual transfer line 1651′ extends to the edge of the array substrate 10 in the first direction X, and the first test circuit 161, the second test circuit 162 and the first test signal line 163 are each connected to the residual transfer line 1651′.

FIG. 16 is a sectional view of a display panel shown in FIG. 4 or FIG. 5 taken along a section line B-B′. FIG. 17 is another sectional view of a display panel shown in FIG. 4 or FIG. 5 taken along a section line B-B′. The display pane 100 in some embodiments of the present disclosure will be schematically described below with reference to FIGS. 16 and 17.

In some embodiments, as shown in FIG. 16, the array substrate 10 includes a first substrate 11, a gate metal layer 12, a gate insulating layer 13, a semiconductor layer 14, a source-drain metal layer 15, a first interlayer insulating layer 16, a first planarization layer 191, an electrode layer 18 and a second planarization layer 192 that are stacked in sequence.

As shown in FIG. 16, the gate metal layer 12 includes the gate 214 of the thin film transistor 210. The semiconductor layer 14 includes the active layer 211 of the thin film transistor 210. The source-drain metal layer 15 includes the source 212 and the drain 213 of the thin film transistor 210. The electrode layer 18 includes the pixel electrode 22 and the common electrode 23, that is, the pixel electrode 22 and the common electrode 23 are arranged in the same layer and made of the same material. In this case, the pixel electrode 22 and the common electrode 23 are each of a comb structure including a plurality of strip sub-electrodes.

On this basis, as shown in FIGS. 16 and 25, the above peripheral connection lines 130 and test connection lines 1652 may be located in the gate metal layer 12. The above cut-off transfer lines 1651 and residual transfer lines 1651′ may be located in the electrode layer 18. The above test pads 164, driving pads 110 and bonding pins 120 may each have a multi-layer stacked structure.

For example, referring to FIGS. 8, 16, 18 and 25, the test pad 164 includes three-layer stacked test sub-pads. The three-layer stacked test sub-pads are respectively located in the gate metal layer 12, the source-drain metal layer 15 and the electrode layer 18. The driving pad 110 includes three-layer stacked driving sub-pads, and the three-layer stacked driving sub-pads are respectively located in the gate metal layer 12, the source-drain metal layer 15 and the electrode layer 18. The bonding pin 120 includes three-layer stacked bonding sub-pins, and the three-layer stacked bonding sub-pins are respectively located in the gate metal layer 12, the source-drain metal layer 15 and the electrode layer 18.

In some other embodiments, as shown in FIG. 17, the array substrate 10 includes a first substrate 11, a gate metal layer 12, a gate insulating layer 13, a semiconductor layer 14, a source-drain metal layer 15, a first interlayer insulating layer 16, a common electrode layer 181, a second interlayer insulating layer 19, a first planarization layer 191, a pixel electrode layer 182 and a second planarization layer 192 that are stacked in sequence.

As shown in FIG. 17, the gate metal layer 12 includes the gate 214 of the thin film transistor 210. The semiconductor layer 14 includes the active layer 211 of the thin film transistor 210. The source-drain metal layer 15 includes the source 212 and the drain 213 of the thin film transistor 210. The common electrode layer 181 includes the common electrode 23. The pixel circuit layer 182 includes the pixel electrode 22.

On this basis, as shown in FIGS. 17 and 25, the above peripheral connection lines 130 and test connection lines 1652 may be located in the gate metal layer 12. The above cut-off transfer lines 1651 and residual transfer lines 1651′ may be located in the pixel circuit layer 182. The above test pads 164, driving pads 110 and bonding pins 120 may each have a multi-layer stacked structure.

For example, referring to FIGS. 8, 17, 18 and 25, the test pad 164 includes four-layer stacked test sub-pads. The four-layer stacked test sub-pads are respectively located in the gate metal layer 12, the source-drain metal layer 15, the common electrode layer 181 and the pixel electrode layer 182. The driving pad 110 includes four-layer stacked driving sub-pads, and the four-layer stacked driving sub-pads are respectively located in the gate metal layer 12, the source-drain metal layer 15, the common electrode layer 181 and the pixel electrode layer 182. The bonding pin 120 includes four-layer stacked bonding sub-pins, and the four-layer stacked bonding sub-pins are respectively located in the gate metal layer 12, the source-drain metal layer 15, the common electrode layer 181 and the pixel electrode layer 182.

Referring to FIGS. 16 and 17, the above color filter substrate 20 may include a second substrate 220, and a color filter layer 230 and a black matrix 24 that are disposed on the second substrate 220.

As shown in FIGS. 16 and 17, the color filter layer 230 includes a plurality of photoresist units 231 with different colors. The black matrix 24 is used to separate the plurality of photoresist units with different colors. For example, the color filter layer 230 includes red photoresist units, green photoresist units, and blue photoresist units.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. An array substrate having a display area and a first frame area arranged in a first direction; the first frame area including a chip setting area and bonding areas; in a second direction, the bonding areas being located on at least one side of the chip setting area; the second direction intersecting the first direction;
the array substrate comprising:
a plurality of driving pads disposed in the chip setting area;
a plurality of bonding pins disposed in a bonding area; and
a plurality of peripheral connection lines disposed in the first frame area; an end of each peripheral connection line being connected to a driving pad, and another end of each peripheral connection line being connected to a bonding pin, wherein
the plurality of peripheral connection lines include first peripheral connection lines, the first peripheral connection lines extend to a side of the chip setting area proximate to the bonding area in the chip setting area; an end of a first peripheral connection line is connected to a driving pad in the chip setting area, and another end of the first peripheral connection line is connected to a bonding pin in the bonding area.

2. The array substrate according to claim 1, wherein the plurality of driving pads are arranged into a plurality of driving pad groups, and the plurality of driving pad groups include:
an output pad group including a plurality of output pads arranged in the second direction; and
an input pad group including a plurality of input pads arranged in the second direction, wherein the input pad group is located on a side of the output pad group away from the display area; the first peripheral connection lines extend to the side of the chip setting area proximate to the bonding area between the input pad group and the output pad group; the driving pad connected to the end of the first peripheral connection line is an input pad, the end of the first peripheral connection line is connected to an end of the input pad proximate to the output pad group, and the another end of the first peripheral connection line is connected to an end of the bonding pin proximate to the display area.

3. The array substrate according to claim 2, wherein the plurality of peripheral connection lines further include:
second peripheral connection lines, wherein the second peripheral connection lines extend to the side of the chip setting area proximate to the bonding area at a side of the chip setting area away from the display area; a driving pad connected to an end of a second peripheral connection line is another input pad, the end of the second peripheral connection line is connected to an end of the another input pad away from the output pad group, and another end of the second peripheral connection line is connected to an end of another bonding pin in the bonding area proximate to the display area.

4. The array substrate according to claim 3, wherein the bonding pin connected to the first peripheral connection line is a first bonding pin; the another bonding pin connected to the second peripheral connection line is a second bonding pin; the first bonding pin is farther away from the chip setting area than the second bonding pin, and the second peripheral connection line is located at a side of the first peripheral connection line away from of the display area.

5. The array substrate according to claim 3, wherein the input pad group includes a plurality of input pad sub-groups, and the input pad sub-groups each include multiple input pads disposed adjacently and for transmitting a same signal;
the second peripheral connection lines include:
at least one first type of second peripheral connection line connected to a bonding pin and an input pad sub-group; and
a second type of second peripheral connection line connected to a bonding pin and at least two input pad sub-groups, the second type of second peripheral connection line being located on a side of the at least one first type of second peripheral connection line away from the display area.

6. The array substrate according to claim 5, wherein the bonding areas are located on opposite sides of the chip setting area in the second direction;
the at least one first type of second peripheral connection line includes two first type of second peripheral connection lines each connected to an input pad sub-group and a bonding pin on a first side of the chip setting area; the two first type of second peripheral connection lines being disposed away from the display area in sequence; and
the second type of second peripheral connection line includes one second type of second peripheral connection line connected to the bonding pin on the first side of the chip setting area and two input pad sub-groups; the one second type of second peripheral connection line being located on the side of the two first type of second peripheral connection lines away from the display area.

7. The array substrate according to claim 3, wherein the input pad group includes a plurality of input pad sub-groups, and the input pad sub-groups each include multiple input pads disposed adjacently and for transmitting a same signal;
the array substrate further comprises:
an input transfer line disposed in the chip setting area and connected to at least two input pad sub-groups, wherein an input pad sub-group in the at least two input pad sub-groups is further connected to a second peripheral connection line.

8. The array substrate according to claim 7, wherein the bonding areas are located on opposite sides of the chip setting area in the second direction; the second peripheral connection lines include:
two first type of second peripheral connection lines each connected to an input pad sub-group and a bonding pin on a second side of the chip setting area; the two first type of second peripheral connection lines being disposed away from the display area in sequence;
the input transfer line is connected to three input pad sub-groups; in the three input pad sub-groups, two input pad sub-groups and one input pad sub-group are respectively located on opposite sides of an input pad sub-group connected to a first type of second peripheral connection line further away from the display area in the two first type of second peripheral connection lines, and the one input pad sub-group is connected to another first type of second peripheral connection line closer to the display area in the two first type of second peripheral connection lines.

9. The array substrate according to claim 1, further comprising:
a plurality of sub-pixels disposed in the display area;
a plurality of data lines connected to the plurality of sub-pixels;
a plurality of scan lines connected to the plurality of sub-pixels; and
a test circuit connected to the plurality of data lines, the plurality of scan lines and the plurality of sub-pixels; wherein
the sub-pixels include a common electrode; and the test circuit includes:
a first test circuit connected to the plurality of data lines;
a second test circuit connected to the plurality of scan lines; and
a first test signal line connected to the common electrode of the plurality of sub-pixels.

10. (canceled)

11. The array substrate according to claim 9, wherein the test circuit further includes:
first test pads disposed between the plurality of peripheral connection lines and the display area, wherein the first test circuit, the second test circuit, and the first test signal line are connected to the first test pads; or
the test circuit further includes:
a plurality of residual transfer lines disposed between the bonding area and the chip setting area, wherein the residual transfer lines extend to an edge of the array substrate located in the first frame area in the first direction; the first test circuit, the second test circuit, and the first test signal line are connected to the residual transfer lines.

12. (canceled)

13. The array substrate according to claim 9, wherein the plurality of driving pads are arranged into a plurality of driving pad groups, and the plurality of driving pad groups includes an output pad group and an input pad group, the output pad group includes data output pads, and the data output pads are each connected to a data line, wherein
the first test circuit is disposed between the input pad group and the output pad group and is connected to the data output pads; or
the array substrate further has a second frame area, a third frame area and a fourth frame area; the second frame area is located on a side of the display area away from the first frame area; and the third frame area and the fourth frame area are located on opposite sides of the display area in the second direction, wherein the first test circuit is disposed in the second frame area and is connected to the plurality of data lines.

14. (canceled)

15. The array substrate according to claim 9, wherein the plurality of data lines include a first data line, a second data line and a third data line; the plurality of sub-pixels include a sub-pixel connected to the first data line, a sub-pixel connected to the second data line, and a sub-pixel connected to the third data line;
the first test circuit includes:
a first data test line;
a second data test line;
a third data test line;
a first transistor, a first electrode of the first transistor being connected to the first data test line, and a second electrode of the first transistor being connected to the first data line;
a second transistor, a first electrode of the second transistor being connected to the second data test line, and a second electrode of the second transistor being connected to the second data line;
a third transistor, a first electrode of the third transistor being connected to the third data test line, and a second electrode of the third transistor being connected to the third data line; and
a first switch signal line connected to gates of the first transistor, the second transistor and the third transistor.

16. The array substrate according to claim 9, wherein the plurality of sub-pixels are arranged in a plurality of rows and a plurality of columns; the scan lines include a first scan line and a second scan line; the first scan line is connected to sub-pixels in an odd row, and the second scan line is connected to sub-pixels in an even row;
the plurality of driving pads include a plurality of first scan output pads and a plurality of second scan output pads, and the array substrate further comprises:
a first scan connection line connected to the first scan line and a first scan output pad; and
a second scan connection line connected to the second scan line and a second scan output pad; and
the second test circuit includes:
a first scan test line;
a second scan test line;
a fourth transistor, a first electrode of the fourth transistor being connected to the first scan test line, and a second electrode of the fourth transistor being connected to the first scan output pad;
a fifth transistor, a first electrode of the fifth transistor being connected to the second scan test line, and a second electrode of the fifth transistor being connected to the second scan output pad; and
a second switch signal line connected to gates of the fourth transistor and the fifth transistor.

17. (canceled)

18. The array substrate according to claim 9, wherein the plurality of driving pads include scan output pads, and the array substrate further comprises:
a gate driver circuit connected to the plurality of scan lines; and
a gate control signal line connected to the gate driver circuit and a scan output pad; and
the second test circuit includes:
a plurality of gate control test lines connected to the scan output pads.

19. (canceled)

20. The array substrate according to claim 1, wherein the plurality of driving pads are arranged into a plurality of driving pad groups, and the plurality of driving pad groups include:
an output pad group including a plurality of output pads arranged in the second direction; and
input pad groups each including a plurality of input pads arranged in the second direction, the input pad groups being located on at least one side of the output pad group in the second direction, wherein
an edge of the plurality of driving pad groups proximate to the display area substantially coincides with an edge of the chip setting area proximate to the display area; the first peripheral connection lines extend to the side of the chip setting area proximate to the bonding area at a side of the plurality of driving pad groups away from the display area; the driving pad connected to the end of the first peripheral connection line is an input pad group, the end of the first peripheral connection line is connected to an end of the input pad group away from the display area, and the another end of the first peripheral connection line is connected to an end of the bonding pin proximate to the display area; or
an edge of the plurality of driving pad groups away from the display area substantially coincides with an edge of the chip setting area away from the display area; the first peripheral connection lines extend to the side of the chip setting area proximate to the bonding area at a side of the plurality of driving pad groups proximate to the display area; the driving pad connected to the end of the first peripheral connection line is an input pad group, the end of the first peripheral connection line is connected to an end of the input pad group proximate to the display area, and the another end of the first peripheral connection line is connected to an end of the bonding pin proximate to the display area.

21. The array substrate according to claim 1, wherein the chip setting area and the bonding areas are each substantially in a rectangular shape; and edges of the bonding areas away from the display area are substantially flush with an edge of the chip setting area away from the display area; or
the chip setting area and the bonding areas are each substantially in a rectangular shape; and edges of the bonding areas away from the display area are substantially flush with an edge of the chip setting area away from the display area; the plurality of peripheral connection lines further include second peripheral connection lines; a distance between the chip setting area and a first edge is a first distance, and a distance between the bonding area and the first edge is a second distance; the first edge is an edge of the first frame area of the array substrate away from the display area; and the first distance is greater than the second distance.

22-24. (canceled)

25. An array motherboard having a plurality of product areas and a plurality of areas to be cut, and every two adjacent product areas having an area to be cut therebetween; the array motherboard comprising the array substrate according to claim 1, and the array substrate being located in a product area.

26. The array motherboard according to claim 25, wherein the array substrate includes a first test circuit, a second test circuit, a first test signal line and a plurality of residual transfer lines; and the array motherboard further comprises:
second test pads disposed in the area to be cut; and
a plurality of test leads disposed in the area to be cut; a test lead being connected to a residual transfer line and a second test pad.

27. (canceled)

28. A display panel, comprising:
the array substrate according to claim 1; and
a color filter substrate disposed opposite to the array substrate, wherein an edge of the first frame area of the array substrate away from the display area exceeds an edge of the color filter substrate corresponding to the first frame area in the first direction, and another edge of the array substrate away from the first frame area and two edges of the array substrate in the second direction are approximately flush with respective edges of the color filter substrate; and the chip setting area, the bonding areas and the peripheral connection lines of the array substrate are all located between the edge of the first frame area of the array substrate away from the display are and the edge of the color filter substrate corresponding to the first frame area.

29. (canceled)

30. A display device, comprising:
the display panel according to claim 28;
a driver chip connected to the driving pads in the array substrate of the display panel; and
a flexible circuit board connected to the bonding pins in the array substrate of the display panel.
